(19) United States
(12) Patent Application Publication
(10) Pub. No.: US 2020/0238437 A1
(43) Pub. Date: Jul. 30, 2020

(54) LASER SEALED HOUSING FOR ELECTRONIC DEVICE

(71) Applicant: Corning Incorporated, Coming, NY (US)

(72) Inventors: Stephan Lvovich Logunov, Corning, NY (US); Mark Alejandro Quesada, Horseheads, NY (US); Alexander Mikhailovich Streltsov, Corning, NY (US)

(21) Appl. No.: 15/754,975

(22) PCT Filed: Aug. 23, 2016
(86) PCT No.: PCT/US16/48103

§ 371 Date: Feb. 23, 2018

Related U.S. Application Data
(60) Provisional application No. 62/208,900, filed on Aug. 24, 2015.

(51) Int. Cl. B23K 26/0622; H01L 51/52; B23K 26/20; B23K 26/211; B23K 26/324

(52) U.S. Cl. CPC B23K 26/0624; H01L 51/5246; B23K 26/324; B23K 26/211; B23K 26/206

(57) ABSTRACT

A laser-welded, sealed electronic device housing and related systems and methods are provided. The sealed housing includes a first substrate having a first surface and a second substrate having a second surface facing the first surface. The sealed housing includes a recess formed in the first substrate. The recess faces the second surface such that the second surface and the recess define a chamber. A laser weld bonds the first surface to the second surface, and the laser weld surrounds the chamber. A functional film is supported by at least one of the first surface and the second surface, and the functional film extends from the chamber and across the laser weld. In exemplary arrangements the device is an OLED device and the functional film form conductive leads in communication with the OLED.

This application claims the benefit of priority under 35 U.S.C. § 119 of U.S. Provisional Application Ser. No. 62/208,900, filed on Aug. 24, 2015, the content of which is relied upon and incorporated herein by reference in its entirety.

### BACKGROUND

The disclosure relates generally to sealed electronic device housing and specifically to hermetically sealed, glass structures for electronic devices, such as organic LEDs (OLEDs). In general, hermetic sealing of OLED displays is needed to provide barriers against materials, such as water and oxygen. Typically, frit sealing is used to adhesively bond together two substrates around each OLED cell in an OLED display.

### SUMMARY

One embodiment of the disclosure relates to a laser-welded, sealed electronic device housing. The housing includes a first substrate having a first surface and a second substrate having a second surface facing the first surface. The housing includes a recess formed in the first substrate, and the recess faces the second surface such that the second surface and the recess define a chamber. The housing includes a laser weld bonding the first surface to the second surface, and the laser weld surrounds the chamber. The housing includes a functional film supported by at least one of the first surface and the second surface, and the functional film extends from the chamber and across the laser weld.

An additional embodiment of the disclosure relates to a sealed electronic device. The device includes a first glass substrate having a first surface and a second glass substrate having a second surface facing the first surface. The device includes a chamber defined between the first surface and the second surface. The device includes a hermetic seal surrounding the chamber, and the seal is formed from a portion of the first substrate joined together with a portion of the second substrate. The device includes a functional film forming extending from the chamber and across the seal.

An additional embodiment of the disclosure relates to a method of forming a sealed electronic device housing. The method includes providing a first substrate having a first surface. The method includes providing a second substrate having a second surface. The method includes forming a recess in the first surface of the first substrate. The method includes placing the first substrate adjacent to the second substrate such that first surface faces the second surface and the recess forms a chamber with an opposing portion of the second surface of the second substrate. The method includes providing a functional film on at least one of the first surface and the second surface. The method includes forming a weld between the first surface and the second surface using a laser, wherein the weld surrounds the chamber and traverses the functional film, and the functional film extends from the chamber across the weld.

Additional features and advantages will be set forth in the detailed description that follows, and, in part, will be readily apparent to those skilled in the art from the description or recognized by practicing the embodiments as described in the written description and claims hereof, as well as the appended drawings.

It is to be understood that both the foregoing general description and the following detailed description are merely exemplary, and are intended to provide an overview or framework to understand the nature and character of the claims.

The accompanying drawings are included to provide a further understanding and are incorporated in and constitute a part of this specification. The drawings illustrate one or more embodiment(s), and together with the description serve to explain principles and the operation of the various embodiments.

### BRIEF DESCRIPTION OF THE DRAWINGS

FIG. 1 shows a top view of a laser sealed electronic device according to an exemplary embodiment.

FIG. 2 shows a side cross-sectional view of a laser sealed electronic device according to an exemplary embodiment.

FIG. 3 shows a detailed view of a lead traversing a laser weld of the electronic device of FIG. 2 according to an exemplary embodiment.

FIGS. 4A-4D shows a schematic view of a process for forming a laser sealed electronic device according to an exemplary embodiment.

### DETAILED DESCRIPTION

Referring generally to the figures, various embodiments of a sealed electronic device, such as a sealed OLED device, are shown and described. In general, the sealed electronic device discussed herein includes two opposing substrates (e.g., glass sheet substrates) with a recess or chamber formed between the two substrates, and an active component, such as an OLED, located within the chamber. A weld surrounds the chamber hermetically sealing the active component within the chamber. In specific embodiments, the weld is a laser weld formed by portions of the first and second substrates that are joined or melted together using a laser. Thus, in general the laser welds discussed herein are cohesive structures which form a strong and hermetic seal around the chamber. In various embodiments, a functional film is located on at least one of the substrates and forms a path extending from the chamber and across the laser weld, and in specific embodiments, the functional film is a conductive material forming first and second electrically conductive leads extending across the laser weld providing electrical conduction to the active component located with the chamber. As will be understood, sealing of conventional electronic devices that utilize frit-based sealing is based on adhesive bonding between the frit and the adjacent substrate materials. In contrast to the conventional frit sealed devices, the laser-welded electronic devices discussed herein provides cohesive laser welds having low thickness and high weld strength as compared to frit sealed devices.

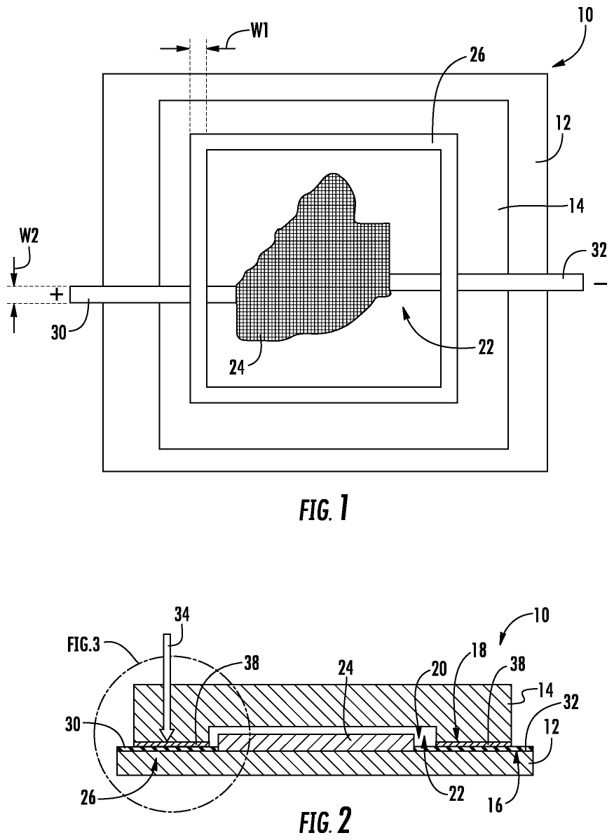

Referring to FIGS. 1 and 2, a sealed electronic device housing an electronic device, shown as OLED device 10, is shown. OLED device 10 includes first and second substrates, shown as bottom substrate 12 and upper substrate 14. Bottom substrate 12 includes a first surface, shown as upper surface 16, facing a second surface, shown as lower surface 18, of upper substrate 14. In general, substrates 12 and 14 are sheets of a glass material (e.g., soda-lime glass, Gorilla® glass sheet material available from Corning, Inc, Eagle XG® glass sheet material available from Corning, Inc., etc.). In the arrangement shown, upper surface 16 and lower surface 18 are major surfaces of the substrates.

At least one of substrates 12 and 14 includes a recess formed in the material of the substrate. In the embodiment shown, a recess 20 is formed in upper substrate 14. When upper substrate 14 is located on lower substrate 12, as shown in FIG. 2, a chamber 22 is defined between the portion of the lower surface of upper substrate 14 defining recess 20 and a portion of upper surface 16 of lower substrate 12. Chamber 22 includes a space within which an active component, such as an active electronic component, shown as OLED 24, is located. While FIG. 2 shows recess 20 and chamber 22 as substantially rectangular in cross-sectional shape, recess 20 and chamber 22 may be any suitable shape for containing an active electronic component, such as OLED 24, including various curved or dome shapes. In various embodiments, the active electronic component may also be an organic electronic device or organic-inorganic hybrid electronic device.

In various embodiments, OLED device 10 may be used in a variety of applications such as electronic displays, and may be used in small displays such as mobile device displays or large displays such as TV displays, monitors, etc. In various embodiments, the active component may be any electronic component, including various semi-conductor devices, including photovoltaic devices. In various embodiments, the hermetic encapsulation of an active component using the materials and methods disclosed here can facilitate long-lived operation of devices otherwise sensitive to degradation by oxygen and/or moisture. In exemplary embodiments, device 10 includes flexible, rigid or semi-rigid organic LEDs, OLED lighting, OLED televisions, MEMs displays, electrochromic windows, fluorophores, alkali metal electrodes, transparent conducting oxides, quantum dots, etc.

Device 10 includes a hermetic seal, shown as laser weld 26 surrounding chamber 22. In general, laser weld 26 bonds together substrates 12 and 14 coupling the substrates relative to each other and hermetically sealing OLED 24 within chamber 22. In one embodiment, laser weld 26 is a closed perimeter seal formed between substrates 12 and 14.

As will be understood, frit sealed electronic devices include a bead of frit that is melted between opposing substrates such that adhesive bonds are formed between the frit and both of the opposing substrates, and in this type of arrangement, the frit material adhesively bonded between the substrates act to form the hermetic seal around the OLED. In contrast to frit sealed devices, laser weld 26 is a cohesive structure formed from opposing portions of substrates 12 and 14 that are joined together, such as by melting. It is believed that the cohesive weld structure of laser weld 26 provides stronger bonding with a lower overall thickness as compared to the adhesive-based bonding structure of a frit sealed electronic device. It should be understood that as used herein joining together of substrates includes a weld formed by one or both of the substrates attaining viscoelastic flow from increased temperatures (e.g., laser induced temperatures) and being thermo-compressed together, a diffusion weld and/or a weld formed where the melting point of the substrates is exceeded. In various embodiments, within laser weld 26, the fictive temperature of the material of substrates 12 and 14 is changed relative to the fictive temperature of the material of substrates 12 and 14 outside of laser weld 26. In specific embodiments, within laser weld 26, the fictive temperature of the material of substrates 12 and 14 is greater than the fictive temperature of the material of substrates 12 and 14 outside of laser weld 26. In one embodiment, laser weld 26 can be reinforced with a perimeter seal surrounding OLED 24.

Device 10 includes at least one functional film material supported by at least one of substrates 12 and 14 and that forms a path extending from within chamber 22 and across laser weld 26. In the embodiment shown in FIGS. 1 and 2, the functional film is a material located on (e.g., in direct contact with) upper surface 16 of lower substrate 12 forming a first lead 30 and a second lead 32. Leads 30 and 32 provide electrically conductive paths extending from within chamber 22 and across laser weld 26, and in particular, leads 30 and 32 are electrically coupled OLED 24, such as to deliver electrical power to OLED 24. As will be explained in more detail below, leads 30 and 32 are formed from one or more material that maintains electrical conductivity even after formation of laser weld 26 while also allowing hermetic sealing of the melted portions of substrates 12 and 14 around the leads.

In various embodiments, laser weld 26 may be formed in a variety of suitable ways in which the materials of substrates 12 and 14 are melted together through the use of laser energy shown schematically in FIG. 2 as laser 34. In one embodiment, laser 34 may be a short pulse laser of sufficient energy to melt together portions of substrates 12 and 14 to form laser weld 26, and in such embodiments, a laser absorption film is not used to form laser weld 26. In another embodiment, at least one of substrates 12 and 14 includes a laser absorbing film 38. In the specific embodiment shown, laser absorbing film 38 is located on lower surface 18 of upper substrate 14 opposing the material of leads 30 and 32. In this specific arrangement, leads 30 and 32 have surfaces that are in contact with laser absorbing film 38. In general, laser absorbing film 38 absorbs energy from laser 34 facilitating melting of substrates 12 and 14 and formation of laser weld 26. In specific embodiments, substrates 12 and 14 are translucent/transparent (e.g., 60%, 70%, 80%, 90% transmission) to laser 34 allowing laser 34 to pass through at least one of the substrates and to interact with laser absorbing film 38.

In various embodiments, laser weld 26, leads 30 and 32, and laser absorbing film 38 are sized and structured to facilitate formation of a low-thickness, hermetically sealed electronic device. As shown in FIG. 1, laser weld 26 has a width, W1, and leads 30 and 32 have widths, W2. In various embodiments, W1 is between 20 μm and 700 μm, and W2 is between 50 μm and 20 mm. In such embodiments, widths of the components discussed herein are the minor dimensions of the components measured in a direction parallel to the major surfaces of the substrates.

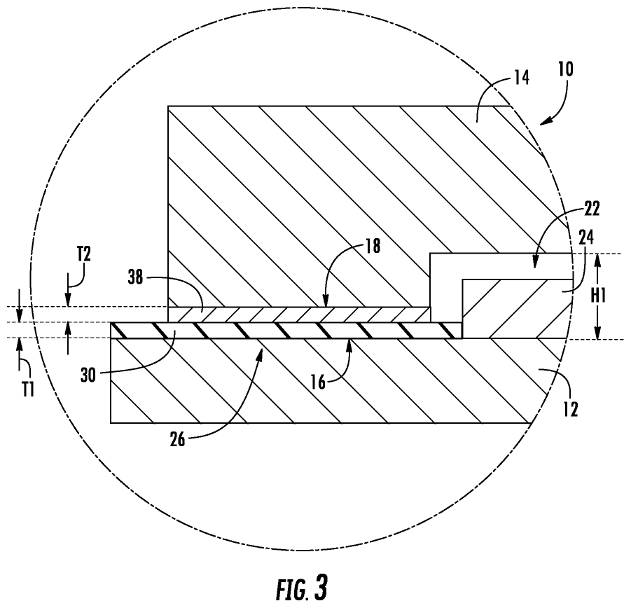

Referring to FIG. 3, a detailed view of a portion of device 10 at laser weld 26 is shown according to an exemplary embodiment. As shown in FIG. 3, lead 30 has a thickness, T1, laser absorbing film 38 has a thickness, T2, and chamber 22 has a height, H1. In various embodiments, T1 is between 20 nm and 1 μm, and in a specific embodiment, both leads 30 and 32 have thicknesses within this range. In various embodiments, T2 is less than 1.5 μm, and in a specific embodiment, is between 0.2 μm and 1 μm. In various embodiments, H1 is between 0.3 μm and 500 μm, specifically is between 1 μm and 10 μm, and more specifically is between 1 μm and 5 μm. In a specific embodiment, H1 is between 3 μm and 4 μm.

In various embodiments, the relative sizes of leads 30 and 32, chamber 22 and laser weld 26 facilitate formation of device 10 having a low total thickness. For example, in one embodiment, T2 is less than 20% of H1. In another embodiment, T1 is less than 20% of H2. In a specific embodiment, both T1 and T2 are less than 20% of H1. In such embodiments, thicknesses or heights of the components discussed herein are the dimensions of the components measured in a direction perpendicular to the major surfaces of the substrates. In some embodiments, the widths, thicknesses and heights discussed herein represent maximum measured dimensions, and in other embodiments, the widths, thicknesses and heights discussed herein represent average measured dimensions. In various embodiments, the width of laser weld 26 is larger than absorbing film 38 thickness. For example, the width and/or thickness of the portion of the substrates that have a change in glass fictive temperature around laser weld 26 is greater than the thickness of absorbing film 38. In various embodiments, the width and/or thickness of of the entire weld region (including the residual stress portion) exceeds the thickness of the absorbing film 38. A survey of the local density distribution, or fictive temperature distribution, in the vicinity of the weld can be used to determine this relative dimensions.

As noted above, in various embodiments, because laser 34 forms laser weld 26 over and around leads 30 and 32, leads 30 and 32 are structured to maintain a satisfactory level of conductivity following formation of laser weld 26. In particular, leads 30 and 32 are structured such that the temperature needed to cause the melting of the materials of substrates 12 and 14 does not eliminate or significantly reduce the conductivity of leads 30 and 32. In various exemplary embodiments, leads 30 and 32 are formed from a material having a melting temperature that is greater than the melting temperature of the material of substrates 12 and 14. In various embodiments, leads 30 and 32 are formed from a material having a melting temperature that is at least 10% greater than the melting point temperature and/or the softening point temperature of the material of substrates 12 and 14. In a specific embodiment, leads 30 and 32 are formed from a material having a melting temperature that is greater than 700 degrees C., and in another embodiment, leads 30 and 32 are formed from a material having a melting temperature that is greater than 800 degrees C. In a specific embodiment, leads 30 and 32 are formed from a material having a melting temperature that is between 800 degrees C. and 900 degrees C. In such embodiments, substrates 12 and 14 may be made from a soda-lime glass material having a softening point of about 700 degrees C., and in other embodiments, substrates 12 and 14 may be made from Eagle XG® glass sheet material available from Corning, Inc. which has a softening point of about 970 degrees C. In various embodiments, leads 30 and 32 are made from a material that experiences an increase in resistivity following formation of laser weld 26 that is less than 30%.

In various embodiments, leads 30 and 32 may be formed from any suitable conductive material. In specific embodiments, leads 30 and 32 are formed from at least one of indium tin oxide (ITO), molybdenum, silver, or copper. In various embodiments, laser absorbing film 38 is formed from any material suitable for absorbing laser energy to facilitate melting of substrates 12 and 14 to form laser weld 26. In various embodiments, laser absorbing film 38 is a material that absorbs any suitable wavelength of laser energy including ultraviolet spectrum laser energy, infrared spectrum laser energy, near infrared spectrum laser energy and visible spectrum laser energy. In specific embodiments, laser absorbing film 38 is a material that absorbs in the 200-410 nm wavelength range, and in other embodiments, laser absorbing film 38 is a material that absorbs in the 800-1900 nm wavelength range.

In specific embodiments, laser absorbing film 38 is formed from at least one of a low melting glass (LMG) having a Tg less than 600 degrees C., ZnO, SnO, TiO₂, Nb₂O₅, and a glass film doped with a transition metal, such as Fe, Mn, Cu, Va, Cr. In some embodiments, laser absorbing film 38 is absorbing at a non-visible spectrum of laser 34 while being transparent/translucent to visible light. In a specific embodiment, the laser absorbing film and substrates 12 and 14 are transparent to light within a wavelength range of 420 nm to 750 nm. In some other embodiments, laser absorbing film 38 is absorbing at a non-visible spectrum of laser 34 while being opaque to visible light.

It should be understood that while most of the embodiments discussed herein discuss formation of a device having a functional film material that acts as leads for an active device such as OLED 24, in other embodiments, device 10 may include other functional films. For example, in one embodiment, the functional film traversing laser weld 26 may be a protective film material, such as an SiN film. Further, it should be understood that while FIGS. 2 and 3, show leads 30 and 32 as a single layered film, in other embodiments, the functional films discussed herein may include multiple layers, such as a film stack. Further, the functional films and/or laser absorbing films discussed herein may be supported from substrates 12 and 14 via one or more intervening layer, and in other embodiments, the functional films and/or laser absorbing films discussed herein may be supported from substrates 12 and 14 via direct contact with the material of the substrates.

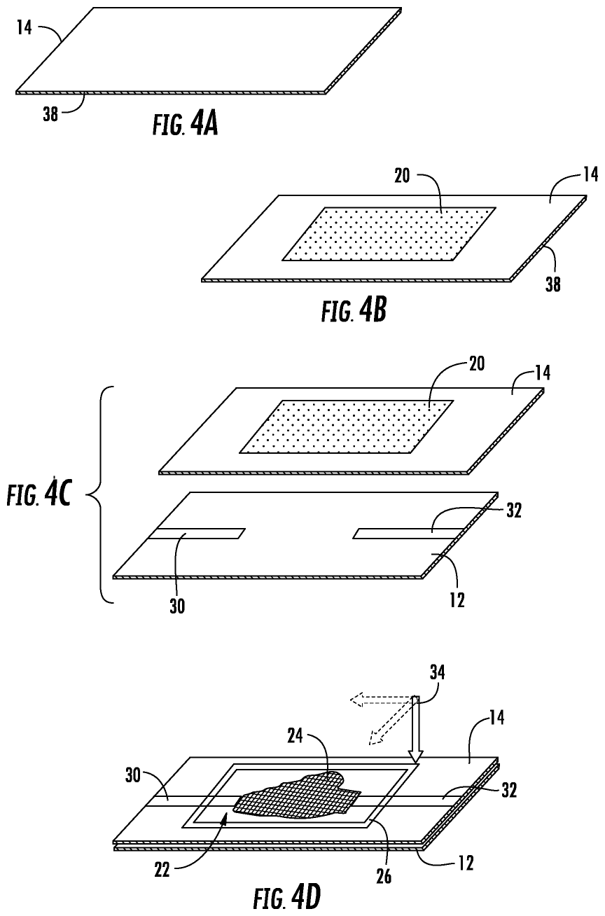

Referring to FIGS. 4A-4D, a method of forming a sealed electronic device, such as device 10, is shown according to an exemplary embodiment. In general, FIGS. 4A-4D show that a first substrate, such as upper substrate 14, and a second substrate, such as lower substrate 12, are provided. As shown in FIG. 4B, a recess is formed in one of the substrates, and in the specific embodiment shown, recess 20 is formed in substrate 14. As shown FIG. 4C, substrate 14 is placed adjacent to substrate 12 such that recess 20 will form a chamber (e.g., chamber 22) with the opposing upper surface of substrate 12. A a functional film, such as leads 30 and 32, is provided on one of the surfaces of substrates 12 and 14.

As shown in FIG. 4D, a weld, such as laser weld 26, is formed between the opposing surfaces of substrates 12 and 14. A laser, such as laser 34 may be moved, aimed or otherwise directed onto substrates 12 and 14 such that laser weld 26 is formed surrounding chamber 22. As discussed above, leads 30 and 32 extend into chamber 22.

As shown in FIGS. 4A and 4B, substrate 14 may be provided with laser absorbing film 38 along one surface of the substrate. As shown in FIG. 4B, a portion of laser absorbing film 38 is removed from within the region that forms recess 20, and in this arrangement, the remaining portion of laser absorbing film 38 surrounds recess 20. In various embodiments, the portion of laser absorbing film 38 is removed from substrate 14 via an etching process, and, recess 20 is formed in substrate 14 via an etching process. In a specific embodiment, the same etching step both removes laser absorbing film 38 and forms recess 20. In various embodiments, etching may be performed with acid or via reactive etching. In other embodiments, CNC mechanical milling may be used to form recess 20 and/or remove the portion of laser absorbing film 38. In such embodiments, etching depth (H1, shown in FIG. 3 above) is controlled by controlling timing of etching. In some embodiments, substrates 12 and 14 may be provided to a OLED device manufacturer, and etching will occur locally immediately prior to sealing with laser 34. In various embodiments, it is believed that the device and methods discussed herein may provide various benefits including: 1) less steps in the manufacturing process, 2) using less expensive phosphor material, and also using less expensive scattering material, 3) better scattering uniformity attributes.

As will be understood, in embodiments in which a laser absorbing film 38 is used, laser 34 has a wavelength selected to interact with the particular laser absorbing film. As noted above, laser 34 may be a UV, IR or visible light laser, and laser absorbing film 38 is selected to absorb within the wavelength of laser 34. In addition, various aspects of laser 34 may be controlled to facilitate formation of laser weld 36 while maintaining the functionality of leads 30 and 32. In various embodiments, the power and scanning speed of laser 34 may be controlled during formation of laser weld 26. For example in some embodiments, laser 34 is a 355 nm laser with a power between 0.1 W and 1.0 W, and specifically, 0.1 W and 0.5 W. In a specific embodiment, laser 34 is a 355 nm laser with a power of 0.6 W and a scanning speed of between 10 mm/s and 50 mm/s, and specifically of 25 mm/s, and laser absorbing film 38 is LMG film coating. In such embodiments, the LMG film coating 38 has a thickness of 1 μm, and leads 30 and 32 are ITO leads that have a thickness of 150 nm. In other embodiments, laser 34 may be a laser, such as a short pulse laser, capable of forming laser weld 26 without the absorbing film. In various specific embodiments, the lasers, processes and materials may be any of those disclosed in U.S. Publication No. 2015/0027168 (U.S. application Ser. No. 14/271,797, filed May 7, 2014), which is incorporated herein by reference in its entirety.

As used herein, a hermetic seal and/or hermetically sealed device is one which, for practical purposes, is considered substantially airtight and substantially impervious to moisture and/or oxygen. By way of example, laser weld 26 can be configured to limit the transpiration (diffusion) of oxygen to less than about 10⁻² cm³/m²/day (e.g., less than about 10⁻³ cm³/m²/day), and limit the transpiration (diffusion) of water to about 10⁻² g/m²/day (e.g., less than about 10⁻³, 10⁻⁴, 10⁻⁵ or 10⁻⁶ g/m²/day). In such embodiments, the hermetic seal substantially inhibits air and water from contacting a protected active element, such as OLED 24.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred. In addition, as used herein, the article “a” is intended to include one or more than one component or element, and is not intended to be construed as meaning only one.

It will be apparent to those skilled in the art that various modifications and variations can be made without departing from the spirit or scope of the disclosed embodiments. Since modifications, combinations, sub-combinations and variations of the disclosed embodiments incorporating the spirit and substance of the embodiments may occur to persons skilled in the art, the disclosed embodiments should be construed to include everything within the scope of the appended claims and their equivalents.

1. A laser-welded, sealed housing comprising:
a first substrate having a first surface;
a second substrate having a second surface facing the first surface;
a recess formed in the first substrate, wherein the recess faces the second surface such that the second surface and the recess define a chamber;
a laser weld bonding the first surface to the second surface, wherein the laser weld surrounds the chamber; and
a functional film supported by at least one of the first surface and the second surface, the functional film extending from the chamber and across the laser weld.

2. The laser-welded, sealed housing of claim 1, wherein the laser weld forms a hermetic seal between the first surface and second surface and around the functional film.

3. The laser-welded, sealed housing of claim 2, wherein the hermetic seal is formed from a portion of the first substrate joined together with a portion of the second substrate, wherein the hermetic seal completely surrounds a perimeter of the chamber.

4. The laser-welded, sealed housing of claim 3, further comprising:
a laser absorbing film supported by at least one of the first surface and the second surface and surrounding the chamber, wherein the laser weld bonds the first substrate to the second substrate at the location of the laser absorbing film;
wherein the functional film forms a first lead forming a conductive path extending from the chamber and across the laser weld and a second lead forming a conductive path extending from the chamber and across the laser weld such that the first and second leads are configured to deliver electrical power to a device located in the chamber.

5. The laser-welded, sealed housing of claim 4, wherein the laser absorbing film is located on the first surface, wherein the first lead and the second lead are located on the second surface, wherein the first lead and the second lead each have a surface in contact with the laser absorbing film at the position where the first and second leads, respectively, extend across the laser weld.

6. The laser-welded, sealed housing of claim 4, wherein the width of the laser weld is between 20 μm and 700 μm, and the width of each of the first lead and the second lead is between 50 μm and 20 mm.

7. The laser-welded, sealed housing of claim 6, wherein a thickness of each of the first and second leads is between 20 nm and 1 μm.

8. The laser-welded, sealed housing of claim 7, wherein the thicknesses of the laser absorbing film is less than 1.5 μm.

9. The laser-welded, sealed housing of claim 8, wherein a maximum height of the chamber measured between a surface of the recess and the second surface is greater than 0.3 μm and less than 500 μm, wherein the laser absorbing film has a thickness that is less than 20% of the maximum height of the chamber, wherein the thickness of the first and second leads are less than 20% of the maximum height of the chamber.

10. The laser-welded, sealed housing of claim 4, wherein the melting temperature of the material of the first and second leads is greater than the softening point of the first and second substrates such that an increase in a resistivity of the first and second leads following formation of the laser weld is less than 30%.

11. The laser-welded, sealed housing of claim 4, wherein material of the leads has a melting temperature greater than 700 degrees C.

12. The laser-welded, sealed housing of claim 11, wherein the first and second leads are formed from at least one of indium tin oxide, molybdenum, silver or copper, wherein the laser absorbing film has a thickness between 0.2 μm and 1 μm and is formed from at least one of a low melting glass (LMG) having a Tg less than 600 degrees C., ZnO, SnO, TiO₂, Nb₂O₅, and a glass film doped with a transition metal.

13. The laser-welded, sealed housing of claim 4, wherein the laser absorbing film absorbs energy in at least one of the ultraviolet, infrared or visible spectrums.

14. The laser-welded, sealed housing of claim 4, further comprising at least one of an OLED, organic electronic device or organic-inorganic hybrid electronic device within the chamber and coupled to the first and second leads.

15. A sealed device comprising:
a first glass substrate having a first surface;
a second glass substrate having a second surface facing the first surface;
a chamber defined between the first surface and the second surface;
a hermetic seal surrounding the chamber, the seal formed from a portion of the first substrate joined together with a portion of the second substrate; and
a functional film extending from the chamber and across the seal.

16. The sealed device of claim 15 further comprising a laser absorbing film located on at least one of the first surface and the second surface and surrounding the chamber, wherein the hermetic seal is a laser weld, wherein the functional film defines a lead forming a conductive path extending from the chamber and across the laser weld.

17. The sealed device of claim 16, wherein a thickness of the lead is between 20 nm and 1 μm, wherein the thicknesses of the laser absorbing film is less than 1.5 μm.

18. The sealed device of claim 17 wherein the melting temperature of the material of the lead is greater than the softening point of the first and second substrates, wherein material of the lead has a melting temperature greater than 700 degrees C.

19. A method of forming a sealed housing comprising:
placing a first substrate adjacent to a second substrate such that a first surface of the first substrate faces a second surface of the second substrate and a chamber is defined between the first substrate and the second substrate; and
forming a weld between the first surface and the second surface using a laser, wherein the weld surrounds the chamber and traverses a functional film disposed on at least one of the first surface or the second surface, wherein the functional film extends from the chamber across the weld.

20. The method of claim 19, wherein the first substrate comprises a laser absorbing film located on the first surface, the method further comprising:
removing a portion of the laser absorbing film from the first surface of the first substrate; and
placing the first substrate adjacent to the second substrate such that a remaining portion of the laser absorbing film surrounds the chamber;
wherein the functional film defines a lead forming a conducting path extending from the chamber and across the weld.

21. The method of claim 20, further comprising forming a recess in the first surface of the first substrate, wherein the recess forms the chamber, removing the portion of the laser absorbing film occurs via etching, and forming the recess occurs via etching.

22. The method of claim 21, wherein the same etching step both removes the portion of the laser absorbing film and also forms the recess.

23. The method of claim 20, wherein the laser weld is formed across the lead by directing a laser toward the laser absorbing film causing the material of the first and second substrates to melt together, wherein each of the first and second substrates comprises a glass material.

24. The method of claim 23, wherein a resistivity of the lead remains the same or increases following formation of the laser weld across the lead, wherein the increase of the resistivity is less than 30%.

25. The method of claim 19, wherein forming the weld comprises directing a short pulse laser on to a portion of at least one of the first substrate or the second substrate surrounding the chamber causing the material of the first and second substrates to melt together.
